(19) United States
(12) Patent Application Publication
(10) Pub. No.: US 2026/0068428 A1
(43) Pub. Date: Mar. 5, 2026

(54) LIGHT-EMITTING ELEMENT, AND DISPLAY DEVICE

(71) Applicant: Sharp Display Technology Corporation, Kameyama City, Mie (JP)

(72) Inventors: Satoru YAMAMOTO, Sakai City, Osaka (JP); YOSHIHIRO UETA, Sakai City, Osaka (JP)

(21) Appl. No.: 19/120,857

(22) PCT Filed: Oct. 18, 2022
(86) PCT No.: PCT/JP2022/038712

§ 371 Date: Apr. 14, 2025

(51) Int. Cl. H10K 50/16; H10K 50/115

(52) U.S. Cl. CPC H10K 50/16; H10K 50/115

(57) ABSTRACT

A light-emitting element includes a first electrode, a second electrode, a light-emitting layer being located between the first electrode and the second electrode and including a plurality of quantum dots and a first charge transport layer being located between the first electrode and the light-emitting layer and/or between the second electrode and the light-emitting layer and being in contact with the light-emitting layer. The first charge transport layer includes a plurality of first charge transport materials and a first inorganic filler with which a space between the plurality of first charge transport materials is filled.

### TECHNICAL FIELD

The disclosure relates to a light-emitting element and a display device including the light-emitting element.

### BACKGROUND ART

PTL 1 discloses a light-emitting element including an anode electrode, a hole transport layer, a light-emitting layer including a quantum dot, an electron transport layer, and a cathode electrode in this order.

### CITATION LIST

### Patent Literature

PTL 1: JP 2009-88276 A

### SUMMARY OF INVENTION

### Technical Problem

In a light-emitting element including a quantum dot, as disclosed in PTL 1, in a light-emitting layer, between charge transport materials of a charge transport layer including a hole transport layer and an electron transport layer, a space through which an ion including an anion or a cation can pass may be formed along a layering direction of the light-emitting element. In such a case, when the light-emitting element is driven, an ion is injected together with a carrier from the charge transport layer into the light-emitting layer including an electron and a hole, and the quantum dot in contact with the ion may deteriorate.

### Solution to Problem

A light-emitting element according to an aspect of the disclosure includes a first electrode, a second electrode, a light-emitting layer being located between the first electrode and the second electrode, the light-emitting layer including a plurality of quantum dots, and a first charge transport layer being located between the first electrode and the light-emitting layer and/or between the second electrode and the light-emitting layer, the first charge transport layer being in contact with the light-emitting layer, in which the first charge transport layer includes a plurality of first charge transport materials and a first inorganic filler with which a space between the plurality of first charge transport materials is filled.

A method for manufacturing a light-emitting element according to another aspect of the disclosure is a method for manufacturing a light-emitting element including a first electrode, a second electrode, a light-emitting layer being located between the first electrode and the second electrode, the light-emitting layer including a plurality of quantum dots, and a first charge transport layer being located between the first electrode and the light-emitting layer and/or between the second electrode and the light-emitting layer, the method including applying a mixed solution obtained by mixing a plurality of first charge transport materials and a first inorganic precursor, and denaturing the first inorganic precursor into a first inorganic filler by heating the applied mixed solution.

### ADVANTAGEOUS EFFECTS OF INVENTION

Efficiency and reliability of a light-emitting element are improved by suppressing arrival of ions from a charge transport layer to a light-emitting layer and suppressing deterioration of a quantum dot.

### BRIEF DESCRIPTION OF DRAWINGS

FIG. 1 is a schematic cross-sectional side view of a display device according to a first embodiment, a schematic cross-sectional view of nanoparticles, a schematic cross-sectional view of quantum dots, and a schematic view for illustrating a first inorganic filler with which a space between the nanoparticles is filled, all together.

FIG. 2 is a schematic plan view of the display device according to the first embodiment.

FIG. 3 is a flowchart illustrating an example of a method for manufacturing a light-emitting element according to the first embodiment.

FIG. 4 is a schematic cross-sectional side view of a display device according to a second embodiment, and a schematic view for illustrating a second inorganic filler with which a space between quantum dots is filled, all together.

FIG. 5 is a schematic band diagram in each layer of a light-emitting element according to the second embodiment.

FIG. 6 is a schematic cross-sectional side view of a display device according to a third embodiment.

FIG. 7 is a schematic cross-sectional side view of a display device according to a fourth embodiment.

FIG. 8 is a schematic band diagram in each layer of a light-emitting element according to the fourth embodiment.

FIG. 9 is a schematic cross-sectional side view of a display device according to a fifth embodiment.

FIG. 10 is a schematic cross-sectional side view of a display device according to a sixth embodiment.

FIG. 11 is a schematic cross-sectional side view of a display device according to a seventh embodiment.

### DESCRIPTION OF EMBODIMENTS

### First Embodiment

### Display Device

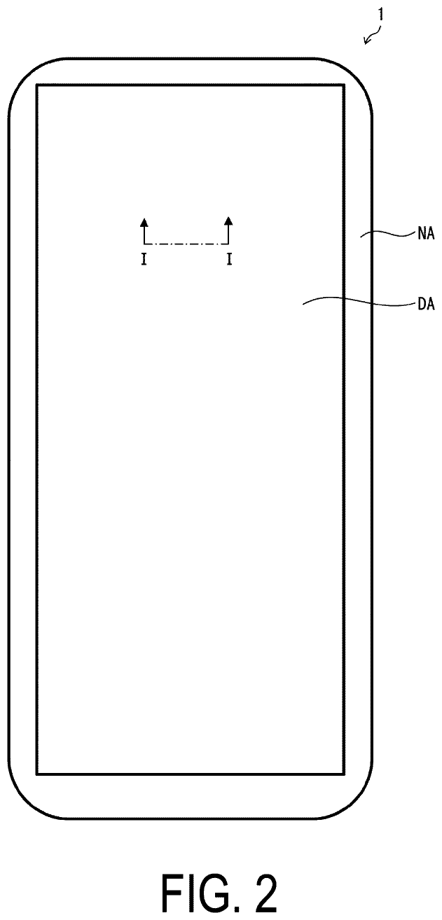

Embodiments of the disclosure will be described below with reference to the drawings. In each drawing, the same components are denoted by the same reference numerals and signs, and description thereof is omitted. FIG. 2 is a schematic plan view of a display device according to the present embodiment.

A display device 1 is a device that can be used for a display of a television, a smartphone, or the like. The display device 1 includes a display portion DA and a frame portion NA formed on the outer circumference of the display portion DA. The display device 1 controls light emission from each of a plurality of light-emitting elements, which will be described below, formed in the display portion DA to perform a display in the display portion DA. In the frame portion NA, a driver or the like for driving each of the plurality of light-emitting elements of the display portion DA may be formed.

The display portion DA of the display device 1 according to the present embodiment may include a plurality of subpixels including a red subpixel, a green subpixel, and a blue subpixel. Each subpixel is formed with a light-emitting element which will be described below, and each light-emitting element individually emits light. Thus, the display device 1 performs a display by individually controlling light emission from the plurality of light-emitting elements of the display portion DA by a driver or the like formed in the frame portion NA, for example.

### Light-emitting Element: Outline

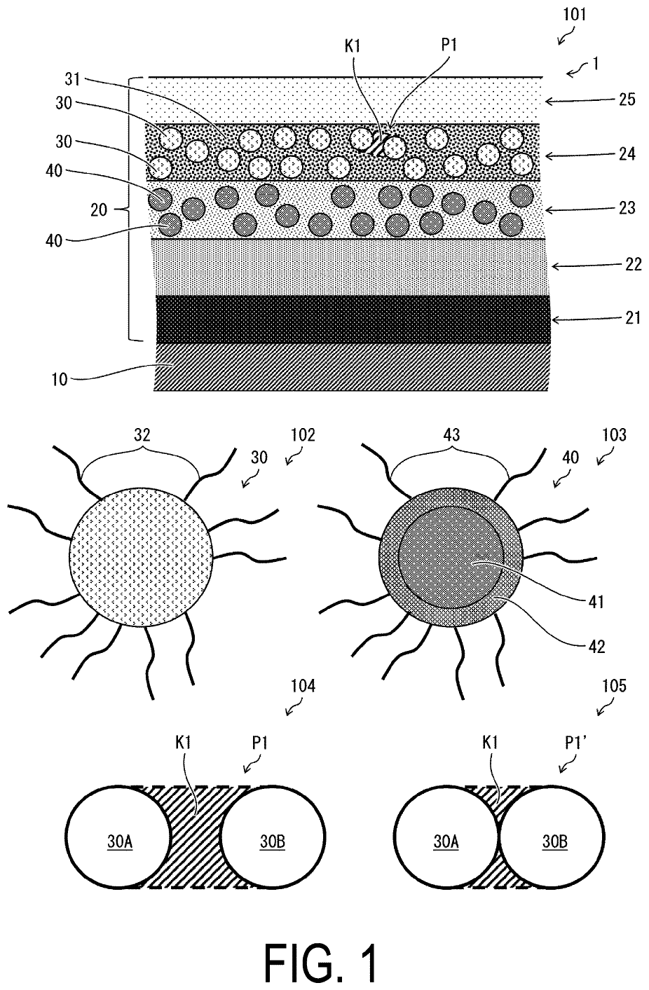

A structure of the display portion DA of the display device 1 according to the present embodiment will be described in more detail with reference to FIG. 1. FIG. 1 illustrates a schematic cross-sectional side view 101 of the display device 1 according to the present embodiment, a schematic cross-sectional view 102 of nanoparticles 30 which will be described below, a schematic cross-sectional view 103 of quantum dots 40, and a schematic view 104 and a schematic view 105 for illustrating a first inorganic filler with which a space between the nanoparticles 30 is filled. In the disclosure, a direction from a substrate 10 of the display device 1 toward light-emitting elements 20 may be described as an “upward direction”, and an opposite direction may be described as a “downward direction”. In the disclosure, “the upward direction” and “the downward direction” are merely examples, and the upper direction and the downward direction may be reversed unless contradiction occurs.

The schematic cross-sectional side view 101 is a cross-sectional view taken along line I-I illustrated in FIG. 2, and is a diagram illustrating a schematic cross section passing through each of the light-emitting elements 20 in a plan view of the substrate 10 of the display device 1 according to the present embodiment. Note that each of the schematic cross-sectional side views of the display device in the disclosure illustrates a cross-section of the display device corresponding to the cross-section illustrated in the schematic cross-sectional side view 101.

The schematic cross-sectional view 102 is a diagram illustrating a cross-section of each of the nanoparticles 30 passing through substantially a center of the nanoparticle 30. The schematic cross-sectional view 102 also illustrates a first ligand 32 coordinated to the nanoparticle 30. The schematic cross-sectional view 103 is a diagram illustrating a cross-section of each of the quantum dots 40 passing through substantially a center of the quantum dot 40. The schematic cross-sectional view 103 also illustrates a second ligand 43 coordinated to the quantum dot 40.

The schematic views 104 and 105 of FIG. 1 illustrate two examples of a set P1 of the two nanoparticles 30 and a region (space) K1 therebetween illustrated in the schematic cross-sectional side view 101, respectively. In particular, the schematic views 104 and 105 illustrate the set P1 and a set P1′, respectively, which are examples of a set of a nanoparticle 30A and a nanoparticle 30B.

As illustrated in the schematic cross-sectional side view 101, the display device 1 includes the substrate 10 and the light-emitting element 20. For example, the display device 1 includes the substrate 10 at a position overlapping the display portion DA and the frame portion NA in a plan view, and further includes the light-emitting element 20 at a position overlapping the display portion DA of the substrate 10. The light-emitting element 20 may be individually formed in each of the plurality of subpixels described above. The display device 1 may include a driver or the like (not illustrated) at a position overlapping the frame portion NA of the substrate 10 in a plan view.

The substrate 10 may include a pixel circuit (not illustrated) corresponding to each subpixel. The pixel circuit may be electrically connected to an anode 21, which will be described below, of the light-emitting element 20. The display device 1 may control a light emission from each light-emitting element 20 by controlling a voltage application to the anode 21 by each pixel circuit through a control of a driver or the like.

The light-emitting element 20 includes, in order from a substrate 10 side, the anode 21 serving as a first electrode, a hole transport layer 22, a light-emitting layer 23, a first charge transport layer, an electron transport layer 24 particularly serving as a first electron transport layer, and a cathode 25 serving as a second electrode. In particular, the hole transport layer 22 is in contact with the light-emitting layer 23 on a side of the anode 21 and the electron transport layer 24 is in contact with the light-emitting layer 23 on a side of the cathode 25. Note that the present embodiment is not limited thereto, and the light-emitting element 20 may include a cathode serving as a first electrode, a first charge transport layer, an electron transport layer particularly serving as a first electron transport layer, a light-emitting layer, a hole transport layer, and an anode serving as a second electrode, in this order from the substrate 10 side.

### Light-Emitting Element: Anode and Cathode

At least one of the anode 21 and the cathode 25 is a transparent electrode through which visible light passes. ITO, InZnO, SnO₂, FTO or the like may be employed for the transparent electrode. One of the anode 21 and the cathode 25 may be a reflective electrode. The reflective electrode may include a metal material having a high reflectance of visible light, and examples of the metal material may include Al, Ag, Cu, or Au alone or an alloy thereof.

### Light-emitting Element: Hole Transport Layer

The hole transport layer 22 is a layer that transports a hole injected from the anode 21 to a side of the light-emitting layer 23. For a material of the hole transport layer 22, an organic or inorganic material having a hole transport property and being conventionally employed in a light-emitting element including quantum dots may be used. Examples of the material of the hole transport layer 22 include poly[(9,9-dioctylfluorenyl-2,7-diyl)-co-(4,4′-(N-4-sec-butylphenyl)) diphenylamine)] (abbreviated “TFB”), poly[N,N′-bis(4-butylphenyl)-N,N′-bis(phenyl)-benzidine] (abbreviated “p-TPD”), and polyvinyl carbazole (abbreviated “PVK”). One type of materials may be used alone, or two or more types thereof may be mixed and used as appropriate.

A hole injection layer for injecting a hole from the anode 21 into the hole transport layer 22 may be formed between the anode 21 and the hole transport layer 22. Examples of a material of the hole injection layer include a composite (abbreviated “PEDOT:PSS”) of poly(3,4-ethylenedioxythiophene) (PEDOT) and polystyrene sulfonic acid (PSS), nickel oxide (NiO), and copper thiocyanate (CuSCN). Note that one type of materials may be used alone, or two or more types thereof may be mixed and used as appropriate.

### Light-Emitting Element: Electron Transport Layer

The electron transport layer 24 is a layer that transports an electron injected from the cathode 25 to the light-emitting layer 23. The electron transport layer 24 according to the present embodiment includes the nanoparticles 30 serving as a first charge transport material, in particular, an electron transport material, and a first inorganic filler 31. In the present embodiment, the electron transport layer 24 includes the first ligand 32 capable of being coordinated to the nanoparticle 30. The electron transport layer 24 may have a thickness of, for example, 10 nm or more and 300 nm or less in a layering direction of the light-emitting element 20 from a position in contact with the light-emitting layer 23.

The nanoparticles 30 include a chalcogen, including oxygen, sulfur, or selenium. Examples of the nanoparticles 30 may be nanoparticles of zinc oxide (ZnO), magnesium oxide (MgO), zinc magnesium oxide (MgZnO), zinc sulfide (ZnS), zinc magnesium sulfide (MgZnS), or zinc selenium sulfide (ZnSeS). Note that a chemical formula is a representative example in the disclosure. In the disclosure, the composition ratio described in the chemical formula is desirably stoichiometry in which the actual composition of the compound is the same as the chemical formula but is not necessarily stoichiometry.

The electron transport layer 24 may include a plurality of the above-described nanoparticles 30 having compositions different from each other. When the electron transport layer 24 includes a plurality of electron transport materials having compositions different from each other, it is easy to design a band gap of the electron transport layer 24 by designing a concentration ratio or the like of the electron transport material.

The first ligand 32 includes, for example, a coordination functional group (not illustrated) at an end of a main chain, and when the coordination functional group forms a coordination bond with an outermost peripheral surface of the nanoparticle 30, the first ligand 32 is coordinated to the nanoparticle 30. The first ligand 32 includes the same chalcogen as the nanoparticle 30. As a result, the chalcogen of the first ligand 32 is strongly bonded to the nanoparticle 30, and thus, a defect due to a dangling bond or the like between the nanoparticle 30 and the first ligand 32 is reduced, and a reliability of the electron transport layer 24 is improved.

Note that the electron transport material included in the electron transport layer 24 is not limited to the nanoparticles 30. For example, for the material of the electron transport material, the electron transport layer 24 may use an organic or inorganic material having an electron transport property and being conventionally employed in a light-emitting element or the like including quantum dots. An example of the electron transport material may include 2, 2′, 2″-(1, 3, 5-benzinetriyl)-tris(1-phenyl-1-H-benzimidazole) (abbreviated as “TPBI”). The electron transport material may include a material for adjusting an amount of electrons to be transported, such as polyvinyl pyrrolidone (PVP), polyethyleneimine (PEI), and ethoxylated polyethyleneimine (PEIE). The electron transport material may include only one type of materials described above, or two or more types thereof as appropriate.

The first inorganic filler 31 fills a space between the plurality of nanoparticles 30. “The first inorganic filler 31 fills a space between the plurality of nanoparticles 30” is sufficient that the first inorganic filler 31 fills at least the region K1 between the nanoparticle 30A and the nanoparticle 30B as illustrated in the schematic view 104 of the set P1. In a cross section of the electron transport layer 24, the region K1 is a region surrounded by two straight lines (common outer tangent lines) in contact with the outer peripheries of the nanoparticle 30A and the nanoparticle 30B and the outer peripheries of the nanoparticle 30A and the nanoparticle 30B facing each other. Therefore, as illustrated in the schematic view 105 of the set P1′, even if the nanoparticle 30A and the nanoparticle 30B are close to each other, the region K1 may exist, and the first inorganic filler 31 fills the region K1.

“The first inorganic filler 31 fills a space between the plurality of nanoparticles 30” does not necessarily mean that the region K1 between the nanoparticle 30A and the nanoparticle 30B is entirely formed of only the first inorganic filler 31. For example, a material such as an organic material different from the material of the first inorganic filler 31 may be included in the region K1 between the nanoparticle 30A and the nanoparticle 30B.

In the electron transport layer 24, the first inorganic filler 31 may fill a region other than the plurality of nanoparticles 30. For example, an outer edge (an upper surface and a lower surface) of the electron transport layer 24 may be covered with the first inorganic filler 31. Configuration may be such that a portion of the first inorganic filler 31 is present from the outer edge of the electron transport layer 24 and the nanoparticles 30 is located away from the outer edge. The outer edge of the electron transport layer 24 is not formed entirely of the first inorganic filler 31, and a part of the nanoparticles 30 may be exposed from the first inorganic filler 31. In the electron transport layer 24, the first inorganic filler 31 may refer to a portion excluding the plurality of nanoparticles 30.

The first inorganic filler 31 may include a plurality of the nanoparticles 30 therein. The first inorganic filler 31 may be formed so as to fill a space formed between the plurality of nanoparticles 30. The plurality of nanoparticles 30 may be embedded in the first inorganic filler 31 at intervals.

The first inorganic filler 31 may include a continuous film having an area of 1000 nm² or more along a plane direction orthogonal to a film thickness direction. The continuous film may be a film not separated by a material other than a material constituting the continuous film in one plane. The continuous film may be in a form of an integral film connected by chemical bonding of the first inorganic filler 31 without interruption. In the disclosure, as long as the above-described continuous film can be confirmed in the electron transport layer 24, even in a case where the electron transport layer 24 includes an electron transport material that is not nanoparticles, a space between the electron transport materials may be regarded as being filled with the first inorganic filler 31.

A concentration of the first inorganic filler 31 in the electron transport layer 24 is, for example, an area ratio occupied by the first inorganic filler 31 in a cross section of the electron transport layer 24. This concentration may be 10% or more and 90% or less, or 30% or more and 70% or less in the cross-sectional observation. The concentration may be measured, for example, from an area ratio in an image obtained in the cross-sectional observation.

For a constituent material of the first inorganic filler 31, a semiconductor or an insulator can be used. Examples of the constituent material of the first inorganic filler 31 include a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium sulfide (MgGa₂S₄). The metal oxide may be zinc oxide (ZnO), titanium oxide (TiO₂), tin oxide (SnO₂), tungsten oxide (WO₃), and zirconium oxide (ZrO₂).

The nanoparticles 30 and the first inorganic filler 31 may include the same inorganic material. For example, the nanoparticles 30 may include nanoparticles of zinc oxide, and the first inorganic filler 31 may include a continuous film of zinc oxide. In such a case, the nanoparticles 30 and the first inorganic filler 31 may be distinguished by determining whether the structure is a nanoparticle or a continuous film.

In the disclosure, unless otherwise specified or inconsistent, it is sufficient if a desired configuration is found in a cross-sectional observation at a width of about 100 nm in the structures of inorganic fillers and the like, and it is not necessary for the desired configuration to be observed in all layers.

### Light-Emitting Element: Light-Emitting Layer

The light-emitting layer 23 includes a plurality of the quantum dots 40 serving as a light-emitting material. For example, as illustrated in the schematic cross-sectional view 103, each of the quantum dots 40 has a core/shell structure including a core 41 and a shell 42 covering a periphery of the core 41. In the present embodiment, the light-emitting layer 23 includes the second ligand 43 capable of being coordinated to an outermost peripheral surface of the quantum dot 40.

The core 41 of the quantum dot 40 is injected with holes from the anode 21 and electrons from the cathode 25, and emits light by excitons generated by recombination of the holes and the electrons. The shell 42 of the quantum dot 40 may have a function of protecting the core 41, such as compensating for a defect of the core 41. The quantum dot 40 may have various conventionally well-known structures.

Note that as used in the disclosure, the “quantum dot” is a dot having a maximum width of 100 nm or less. For example, the shape of the quantum dot 40 is not particularly limited as long as the shape is within a range satisfying the maximum width, and the shape is not limited to a spherical three-dimensional shape (circular cross-sectional shape). The shape of the quantum dot 40 may be, for example, a polygonal cross-sectional shape, a rod-like three-dimensional shape, a branch-like three-dimensional shape, or a three-dimensional shape having unevenness on the surface, or a combination thereof.

The quantum dot 40 typically may include a semiconductor. The semiconductor may have a constant band gap. The semiconductor may be a material capable of emitting light and may include at least a material which will be described below. The semiconductor may emit each of blue light, green light, and red light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

For example, similarly to the first ligand 32, the second ligand 43 has a coordination functional group (not illustrated) at an end of the main chain, and the coordination functional group forms a coordination bond with the outermost peripheral surface of the quantum dot 40 to be coordinated to the quantum dot 40. The second ligand 43 includes the same chalcogen as the nanoparticle 30. As a result, defects due to dangling bonds or the like at the interface between the light-emitting layer 23 and the electron transport layer 24 are reduced, and the reliability of the light-emitting layer 23 and the electron transport layer 24 is improved. However, the present embodiment is not limited thereto, and at least a part of the second ligand 43 may be an organic ligand.

### Light-Emitting Element: Manufacturing Method

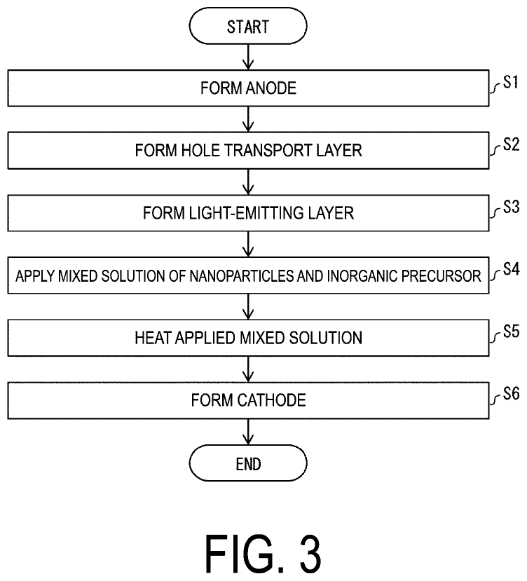

A method for manufacturing the light-emitting element 20 according to the present embodiment will be described with reference to FIG. 3. FIG. 3 is a flowchart illustrating a method for manufacturing the light-emitting element 20 according to the present embodiment.

As illustrated in FIG. 3, in the method for manufacturing the light-emitting element 20 according to the present embodiment, first, the anode 21 is formed (step S1). The anode 21 may be formed by forming a thin film of a metal material on a substrate such as a glass substrate or a film substrate by sputtering or the like. The substrate may be a substrate 10 formed with a pixel circuit for each subpixel in advance. In such a case, the anode 21 may be formed so as to be electrically connected to the pixel circuit, or may be patterned for each subpixel.

Next, the hole transport layer 22 is formed (step S2). The hole transport layer 22 may be formed by applying a material having a hole transport property on the anode 21 to form a film.

Next, the light-emitting layer 23 is formed (step S3). The light-emitting layer 23 may be formed by applying a solution in which the quantum dots 40 are dispersed on the hole transport layer 22 to form a film, and then volatilizing the solvent of the solution by heating. In step S3, the second ligand 43 may be mixed into the solution in which the quantum dots 40 are dispersed. In such a case, the second ligand 43 is coordinated to the quantum dot 40 in the solution to improve the dispersibility of the quantum dot 40. In step S3, the second ligand 43 may remain in the light-emitting layer 23.

When the display device 1 includes a plurality of subpixels, the light-emitting layer 23 may be patterned in step S3. In particular, when the display device 1 includes subpixels having a luminescent color different from each other, formation of the light-emitting layer 23 may be repeatedly executed while changing the luminescent color of the quantum dots 40 in step S3.

For example, in step S3, first, a sacrificing layer including a photosensitive resin is applied to form a film in common for a plurality of subpixels. Next, the sacrificing layer is patterned by photolithography so that the sacrificing layer remains at a position other than a position where the light-emitting layer 23 is formed in a plan view of the substrate 10. Next, a layer including the quantum dots 40 is applied in common to the plurality of subpixels to form a film. Next, the sacrificing layer is removed together with the layer including the quantum dots 40 formed on the sacrificing layer to pattern the light-emitting layer 23 for each specific subpixel. Such a step may be repeatedly executed while changing a luminescent color and a formation position of the quantum dot 40.

Next, a mixed solution of the nanoparticles 30 and an inorganic precursor which is a precursor of the first inorganic fillers 31 is applied onto the light-emitting layer 23 (step S4). In order to improve the dispersibility of the nanoparticles 30 in the mixed solution, the mixed solution may include the first ligand 32 capable of being coordinated to the nanoparticles 30.

Next, the applied mixed solution is heated (step S5). In step S5, for example, each layer including the applied mixed solution is heated in an atmosphere of 250° C. for 30 minutes. Thus, while the solvent of the mixed solution is volatilized, the inorganic precursor in the mixed solution is modified, and the first inorganic filler 31 is formed. Here, the inorganic precursor in the mixed solution is denatured by heating in step S5, and the first inorganic filler 31 is sequentially formed around the nanoparticles 30 in the mixed solution. Accordingly, the first inorganic filler 31 is formed to fill a space between the plurality of nanoparticles 30 in step S5. As described above, the electron transport layer 24 including the plurality of nanoparticles 30 and the first inorganic filler 31 with which a space between the nanoparticles 30 is filled is formed.

Next, the cathode 25 is formed on the electron transport layer 24 (step S6). The cathode 25 may be formed by forming a thin film of a metal material by a sputtering method or the like. Thus, the process of manufacturing the light-emitting element 20 is completed. When the light-emitting element 20 is formed on the substrate 10, the display device 1 may be manufactured according to the above-described manufacturing process of the light-emitting element 20.

### Effects of Light-emitting Element

The light-emitting element 20 includes the electron transport layer 24 serving as a first charge transport layer, in particular, a first electron transport layer in contact with the light-emitting layer 23. The electron transport layer 24 includes the nanoparticles 30 that are a first charge transport material, in particular, an electron transport material, and the first inorganic filler 31 with which a space between the nanoparticles 30 is filled. Therefore, the first inorganic filler 31 is formed in a space formed between the nanoparticles 30.

When a voltage is applied to the light-emitting element 20 including the electron transport material such as the nanoparticles 30 in the electron transport layer 24, anions are generated due to ionization of the electron transport material and may move to a side of the light-emitting layer 23 together with electrons. However, in the electron transport layer 24, the first inorganic filler 31 located in a space between the nanoparticles 30 inhibits movement of the anions and prevents the anions from reaching the light-emitting layer 23. Note that an example of the anion may include a hydroxide ion.

Therefore, in the light-emitting element 20, the electron transport layer 24 reduces deterioration of the quantum dots 40 of the light-emitting layer 23, and improves a reliability and a light-emitting efficiency of the light-emitting element 20. The display device 1 includes the light-emitting element 20 with the improved reliability and light-emitting efficiency, and thus, the lifetime of the display device 1 is prolonged and power saving thereof is achieved.

In the case where an organic ligand is coordinated to the quantum dot 40, the degradation of the organic ligand may progress due to injection of ions into the light-emitting layer 23. Therefore, when the light-emitting layer 23 includes an organic ligand for the second ligand 43 capable of being coordinated to the quantum dot 40, the electron transport layer 24 more strongly exhibits the effect of improving the reliability of the light-emitting layer 23.

In general, a light-emitting element including a quantum dot as a light-emitting material in a light-emitting layer often has an excess of electrons in which the concentration of electrons is higher than the concentration of holes in the light-emitting layer. The excess of electrons in the light-emitting layer increases an occurrence of processes that do not contribute to light emission, such as the generation of Auger electrons, and may degrade the quantum dots, and as a result, a decrease in reliability and luminous efficiency of the light-emitting layer is lead.

In the electron transport layer 24 according to the present embodiment, the electron transport layer 24 includes the first inorganic filler 31, and thus, electrons injected from the cathode 25 are also prevented from moving between the electron transport materials. Therefore, the electron transport layer 24 according to the present embodiment suppresses the transport of electrons from the cathode 25 to the light-emitting layer 23, and thus, the concentration of electrons in the light-emitting layer 23 is reduced. Therefore, the electron transport layer 24 suppresses excess of electrons in the light-emitting layer 23, and further improves the reliability and the luminous efficiency of the light-emitting layer 23.

### Second Embodiment

### Mineralization of Light-Emitting Layer

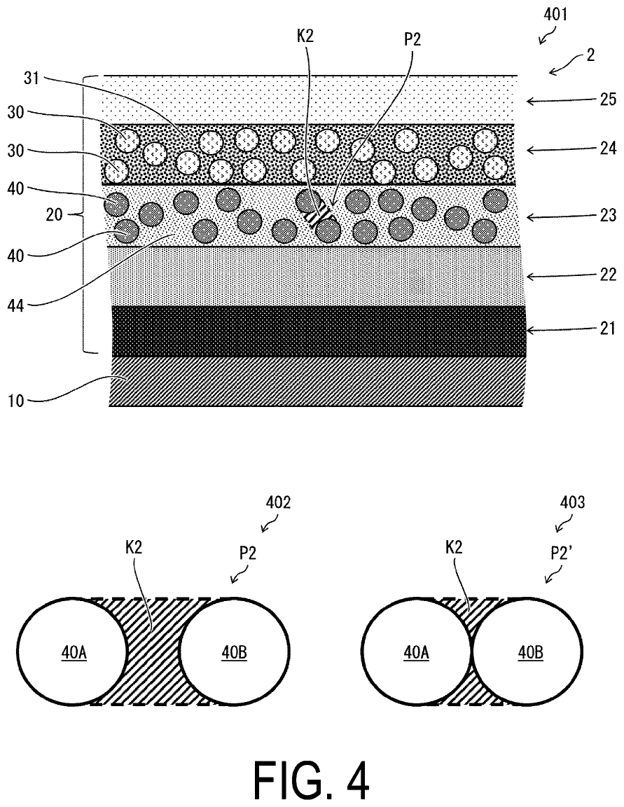

A display device 2 according to the present embodiment will be described with reference to FIG. 4. FIG. 4 is a schematic cross-sectional side view 401 of the display device 2 according to the present embodiment, and a schematic view 402 and a schematic view 403 for illustrating the first inorganic filler with which a space between the quantum dots 40 is filled.

The schematic views 402 and 403 of FIG. 4 respectively illustrate two examples of a set P2 of two quantum dots 40 and a region (space) K2 therebetween illustrated in the schematic cross-sectional side view 401. In particular, the schematic views 402 and 403 are diagrams illustrating sets P2 and P2′ which are examples of a set of a quantum dot 40A and a quantum dot 40B, respectively.

The display device 2 according to the present embodiment has the same configuration as the display device 1 according to the previous embodiment except for the light-emitting layer 23. The light-emitting layer 23 according to the present embodiment has the same configuration as that of the light-emitting layer 23 according to the previous embodiment except that the second inorganic filler 44 is provided.

The second inorganic filler 44 fills a space between the plurality of quantum dots 40. Note that “the second inorganic filler 44 fills a space between the plurality of quantum dots 40” is sufficient that at least the region K2 between the quantum dot 40A and the quantum dot 40B is filled as illustrated in the schematic view 402 of the set P2 illustrated in FIG. 4. In the cross section of the light-emitting layer 23, the region K2 is a region surrounded by two straight lines (common outer tangent lines) in contact with the outer peripheries of the quantum dot 40A and the quantum dot 40B and the outer peripheries of the quantum dot 40A and the quantum dot 40B facing each other. Therefore, as illustrated in the schematic view 403 of the set P2′ illustrated in FIG. 4, even if the quantum dot 40A and the quantum dot 40B are close to each other, the region K2 may exist, and the second inorganic filler 44 fills the region K2.

“The second inorganic filler 44 fills a space between the plurality of quantum dots” does not necessarily mean that the entire region K2 between the quantum dots 40A and the quantum dots 40B is formed only of the second inorganic filler 44. For example, a material such as the second ligand 43 different from the material of the second inorganic filler 44 may be included in the region K2 between the quantum dot 40A and the quantum dot 40B. Specifically, for example, the light-emitting layer 23 may include an organic ligand added to improve the dispersibility of the quantum dots in a solution used for forming application and coordinated to the outer peripheral surface of the quantum dots 40 in the solution. In such a case, in the light-emitting layer 23, the weight ratio of the organic ligand to the total weight including the region K2 may be less than 5%, for example, from the viewpoint of improving the reliability of the light-emitting layer 23.

The second inorganic filler 44 may fill a region (space) other than a region including the plurality of quantum dots 40 in the light-emitting layer 23. For example, the outer edges (upper surface and lower surface) of the light-emitting layer 23 may be covered with the second inorganic filler 44. Configuration may be such that a portion of the second inorganic filler 44 may be located from the outer edge of the light-emitting layer 23, and the quantum dots 40 may be located away from the outer edge. The outer edge of the light-emitting layer 23 is not formed of only the second inorganic filler 44, and a part of the quantum dots 40 may be exposed from the second inorganic filler 44. The second inorganic filler 44 may be indicated as a portion of the light-emitting layer 23 excluding the plurality of quantum dots 40.

On the other hand, in the present embodiment, the second inorganic filler 44 may not fill the surroundings of all the quantum dots 40 included in the light-emitting layer 23. For example, in the light-emitting layer 23 according to the present embodiment, the second inorganic filler 44 may fill a space between some of the quantum dots 40 on a side of the electron transport layer 24. In such a case, in place of the second inorganic filler 44, a ligand such as an organic ligand coordinated to the quantum dot 40 may be formed in a space between the other of the quantum dots 40.

The second inorganic filler 44 may include the plurality of quantum dots 40 therein. The second inorganic filler 44 may be formed so as to fill a space formed between the plurality of quantum dots 40. The plurality of quantum dots 40 may be embedded in the second inorganic filler 44 at intervals.

The second inorganic filler 44 may include a continuous film having an area of 1000 nm² or more along a plane direction orthogonal to a film thickness direction. The continuous film may be a film not separated by a material other than a material constituting the continuous film in one plane. The continuous film may be in a form of an integral film connected by chemical bonding of the second inorganic filler 44 without interruption.

The concentration of the second inorganic filler 44 in the light-emitting layer 23 is, for example, an area ratio occupied by the second inorganic filler 44 in a cross section of the light-emitting layer 23. This concentration may be 10% or more and 90% or less, or 30% or more and 70% or less in the cross-sectional observation. The concentration may be measured, for example, from an area ratio in an image obtained in the cross-sectional observation. When the quantum dots 40 have a configuration having the core 41 and the shell 42, the concentration of the shell 42 may be 1% or more and 50% or less. The ratio of the core 41, the shell 42, and the second inorganic filler 44 may be adjusted so that the total is 100% or less as appropriate. When the shell 42 and the second inorganic filler 44 cannot be distinguished from each other, the shell 42 may be a part of the second inorganic filler 44.

The light-emitting layer 23 may include the plurality of quantum dots 40 and the second inorganic filler 44. The intensity of carbon detected by a chain structure obtained when the light-emitting layer 23 is analyzed may be equal to or less than a noise level. If the quantum dots 40 in which the organic ligand is coordinated are used in the light-emitting layer 23 as in a well-known art, the carbon chain of the organic ligand may be decomposed, the organic ligand itself may be detached from the quantum dot, or the like due to long-time driving. In such a case, the quantum dots 40 may be deteriorated to cause a decrease in luminance. As in the disclosure, when a space between the quantum dots 40 is filled with the second inorganic filler 44, it is possible to protect the quantum dots 40 without using an organic ligand. Therefore, the display device 1 according to the present embodiment can realize high reliability, in other words, can realize suppression of a decrease in luminance with respect to long-time driving of the light-emitting element 20.

For example, the second inorganic filler 44 may include, for example, the same inorganic material as that of the first inorganic filler 31. Accordingly, the lattice mismatch between the first inorganic filler 31 and the second inorganic filler 44 is reduced. Therefore, with the above-described configuration, in the light-emitting element 20, defects such as dangling bonds at a boundary between the light-emitting layer 23 and the electron transport layer 24 are reduced, and the reliability of the light-emitting layer 23 and the electron transport layer 24 is further improved.

Here, at each position in a plan view of the substrate 10, a first plane connecting points on the cathode 25 side of the quantum dots 40 located closest to the cathode 25 and a second plane connecting points on the anode 21 side of the electron transport materials located closest to the anode 21 are defined. In the case where the first inorganic filler 31 and the second inorganic filler 44 are formed of the same material, the interface between the light-emitting layer 23 and the electron transport layer 24 may be located between the first surface and the second surface, or may be a surface where the distance between the first surface and the second surface is equal. The light-emitting element 20 may include a layer including the first inorganic filler 31 and the second inorganic filler 44 and not including the electron transport material and the quantum dot 40, between the first surface and the second surface.

The light-emitting element 20 according to the present embodiment may be manufactured by the same method as the method for manufacturing the light-emitting element 20 according to the previous embodiment according to the flowchart illustrated in FIG. 3 except for step S3. In the method for manufacturing the light-emitting element 20 according to the present embodiment, in step S3, a mixed solution of the quantum dots 40 and the precursor of the second inorganic filler 44 may be applied onto the hole transport layer 22. Next, the mixed solution may be heated to denature the precursor into the second inorganic filler 44 to produce the light-emitting layer 23 according to the present embodiment. The heating of the mixed solution in step S3 may be performed under the same conditions as for the heating of the mixed solution in step S4 described above.

Also in the present embodiment, the light-emitting layer 23 may be manufactured by patterning the layer including the quantum dots 40. In such a case, the layer including the quantum dots 40 may be exposed to a developing solution or the like used for patterning. In such a case as well, in the layer including the quantum dots 40 already formed, the quantum dots 40 are protected by the second inorganic filler 44 with which a space between the quantum dots 40 is filled. Therefore, according to the manufacturing method described above, it is possible to suppress deterioration of the quantum dots 40 by patterning the light-emitting layer 23.

### Band Diagram of Each Component of Light-Emitting Element

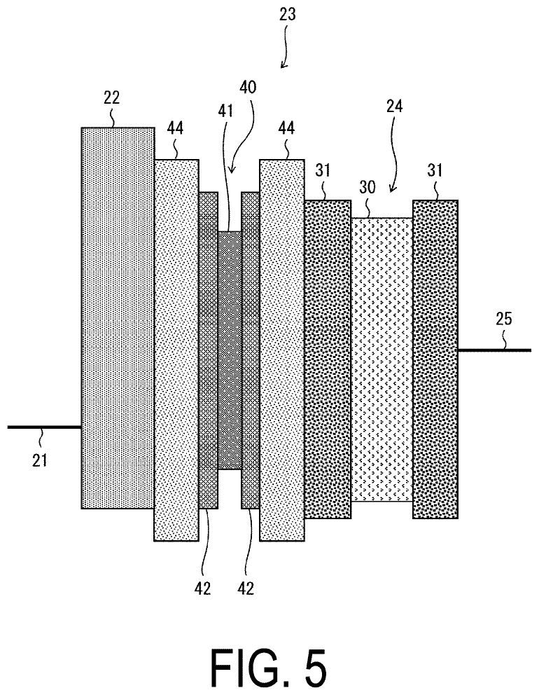

A band gap of components of the light-emitting element 20 according to the present embodiment will be described with reference to FIG. 5. FIG. 5 is a schematic band diagram illustrating an example of a band gap of components of the light-emitting element 20 according to the present embodiment. Note that the band diagram in the disclosure has a vacuum level on the upper side in the drawing. The left-right direction of the band diagram in the disclosure represents the thickness direction in the display direction of the display device, the left side of the drawing is a side of the anode 21, and the right side is a side of the cathode 25.

In the band diagram according to the disclosure, the respective Fermi levels of the anode 21 and the cathode 25 are illustrated. The band gaps of the hole transport layer 22, the light-emitting layer 23, and the electron transport layer 24 are also illustrated. In the band diagram illustrated in FIG. 5, band gaps of the nanoparticles 30 and the first inorganic filler 31 of the electron transport layer 24 are illustrated. Further, the band diagram illustrated in FIG. 5 illustrates a band gap between the core 41 and the shell 42 of the quantum dot 40 of the light-emitting layer 23 and the second inorganic filler 44.

As illustrated in FIG. 5, for example, the band gap of the first inorganic filler 31 is equal to or less than the band gap of the second inorganic filler 44. The electron affinity of the first inorganic filler 31 is equal to or more than the electron affinity of the second inorganic filler 44. Note that in the band diagram according to the disclosure, the electron affinity of each component corresponds to a distance from the vacuum level to the upper end of the band gap. Therefore, in the band diagram of FIG. 5, as the upper end of the band gap of a layer is located at the lower side, the electron affinity of the layer is larger. In other words, as the band gap of a layer increases, the electron affinity of the layer tends to reduce.

An injection barrier of an electron from a first layer to a second layer corresponds to the electron affinity obtained by subtracting the electron affinity of the second layer from the electron affinity of the first layer. Thus, in the present embodiment, when the band gap of the first inorganic filler 31 is equal to or less than the band gap of the second inorganic filler 44, the barrier of electron injection from the first inorganic filler 31 to the second inorganic filler 44 is larger. Therefore, in the light-emitting element 20 according to the present embodiment, the efficiency of electron injection from the cathode 25 to the light-emitting layer 23 is further reduced, and the excess of electrons in the light-emitting layer 23 is further suppressed.

The band gap of the first inorganic filler 31 can be changed by changing the ratio of the materials included in the first inorganic filler 31. Therefore, when the first inorganic filler 31 includes a plurality of materials having compositions different from each other, it is possible to easily design the first inorganic filler 31 having a band gap equal to or less than the band gap of the second inorganic filler 44 described above.

### Third Embodiment

### Second Electron Transport Layer

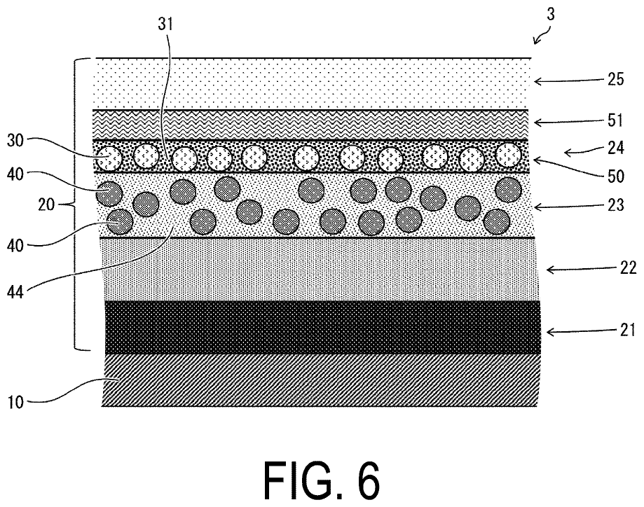

A display device 3 according to the present embodiment will be described with reference to FIG. 6. FIG. 6 is a schematic cross-sectional side view of the display device 3 according to the present embodiment. The display device 3 according to the present embodiment has the same configuration as the display device 2 according to the previous embodiment except for the electron transport layer 24. The electron transport layer 24 according to the present embodiment includes a first electron transport layer 50 in contact with the light-emitting layer 23 and a second electron transport layer 51 in contact with the first electron transport layer 50 in this order from a side of the light-emitting layer 23. In other words, the light-emitting element 20 according to the present embodiment includes the first electron transport layer 50 and the second electron transport layer 51 on a side opposite to the light-emitting layer 23 with respect to the first electron transport layer 50.

The first electron transport layer 50 has the same configuration as the electron transport layer 24 according to each of the previous embodiments except for the thickness. The first electron transport layer 50 may have the thickness of, for example, 1 nm or more and 300 nm or less in the layering direction of the light-emitting elements 20 from the position in contact with the light-emitting layer 23.

The second electron transport layer 51 has the same configuration as the first electron transport layer 50 except that the second electron transport layer 51 does not include the first inorganic filler 31. The second electron transport layer 51 includes an electron transport material such as the nanoparticles 30. The second electron transport layer 51 may have a thickness of, for example, 10 nm or more and 300 nm or less in the layering direction of the light-emitting elements 20 from the position in contact with the first electron transport layer 50.

The light-emitting element 20 according to the present embodiment includes the first electron transport layer 50 being in contact with the light-emitting layer 23 and having the first inorganic filler 31 with which a space between the nanoparticles 30 is filled. Therefore, in the light-emitting element 20, the first inorganic filler 31 can reduce passage of ions between the nanoparticles 30 in the first electron transport layer 50.

The light-emitting element 20 according to the present embodiment includes the first electron transport layer 50 and the second electron transport layer 51. Therefore, in the present embodiment, it is possible to design the first electron transport layer 50 and the second electron transport layer 51 to have different band gaps, and the degree of freedom in designing the light-emitting element 20 is improved.

In particular, the light-emitting element 20 according to the present embodiment includes the second electron transport layer 51 not including the first inorganic filler 31. Therefore, the light-emitting element 20 achieves the above-described suppression of the passage of ions through the electron transport layer 24 while reducing the total amount of the first inorganic filler 31 included in the electron transport layer 24. Therefore, the light-emitting element 20 achieves both cost reduction and improvement in reliability and luminous efficiency of the light-emitting element 20. The second electron transport layer 51 not including the first inorganic filler 31 has a higher carrier mobility and a lower electrical resistance than the first electron transport layer 50, and thus, the electron transport layer 24 according to the present embodiment can reduce the electrical resistance of the entire light-emitting element 20 and achieve power saving.

The light-emitting element 20 according to the present embodiment may be manufactured by the same manufacturing method as the method for manufacturing the light-emitting element 20 in the previous embodiment except for the process for forming the electron transport layer 24. In the method for manufacturing the light-emitting element 20 according to the present embodiment, the concentrations of the nanoparticles 30 and the inorganic precursor with respect to the solvent of the mixed solution may be reduced in step S4. Thus, the first electron transport layer 50 having a reduced film thickness can be formed without changing the application amount of the mixed solution in step S5. Next, the mixed solution including no inorganic precursor may be applied onto the first electron transport layer 50, and then the solvent may be dried. Thus, the second electron transport layer 51 may be formed on the first electron transport layer 50 to form the electron transport layer 24 according to the present embodiment.

### Fourth Embodiment

### Mineralization of Hole Transport Layer

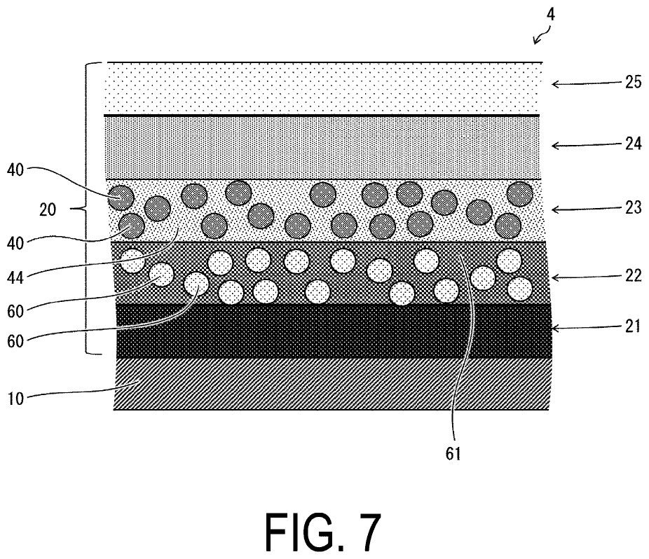

A display device 4 according to the present embodiment will be described with reference to FIG. 7. FIG. 7 is a schematic cross-sectional side view of the display device 4 according to the present embodiment. The display device 4 according to the present embodiment has the same configuration as the above-described display device 2 except for the hole transport layer 22 and the electron transport layer 24.

The electron transport layer 24 according to the present embodiment does not include the first inorganic filler 31. For example, the electron transport layer 24 according to the present embodiment may have the same configuration as the second electron transport layer 51 according to the previous embodiment except for the film thickness.

Furthermore, the hole transport layer 22 according to the present embodiment includes nanoparticles 60 serving as the hole transport material and a third inorganic filler 61 with which a space between the nanoparticles 60 is filled. In other words, the light-emitting element 20 according to the present embodiment includes the hole transport layer 22 which is the first hole transport layer serving as the first charge transport layer, and the hole transport layer 22 includes the nanoparticles 60 serving as the hole transport material which is the first charge transport material. The hole transport layer 22 may be 10 nm or more and 300 nm or less in the layering direction of the light-emitting elements 20 from the position in contact with the light-emitting layer 23.

The nanoparticle 60 may have the same configuration as the nanoparticle 30 except that the nanoparticle 60 includes a hole transport material having hole transport properties. For example, the nanoparticles 60 may include NiO or CuSCN nanoparticles, or may include NiO nanoparticles doped with Ag to improve a hole transport performance. The hole transport layer 22 may have the first ligand 32 capable of being coordinated to the nanoparticle 60. The hole transport layer 22 may not include the nanoparticles 60, and specifically may include the above-described hole transport material instead of the nanoparticles 60.

The third inorganic filler 61 may include the same inorganic material as the above-described first inorganic filler 31. The third inorganic filler 61 may include the same inorganic material as the above-described second inorganic filler 44. The nanoparticles 60 and the third inorganic filler 61 may include the same inorganic material. In the disclosure, filling a space between the nanoparticles 60 with the third inorganic filler 61 may be defined by the same definition as filling a space between the nanoparticles 30 with the first inorganic filler 31.

The third inorganic filler 61 may include a continuous film having an area of 1000 nm² or more along a plane direction orthogonal to a film thickness direction. In the disclosure, as long as the above-described continuous film can be confirmed in the hole transport layer 22, even in a case where the hole transport layer 22 includes a hole transport material other than nanoparticles, a space between the hole transport materials may be regarded as being filled with the third inorganic filler 61.

The light-emitting element 20 includes the hole transport layer 22 serving as a first charge transport layer, in particular, a first hole transport layer in contact with the light-emitting layer 23. The hole transport layer 22 includes the nanoparticles 60 that are a first charge transport material, in particular, a hole transport material, and the third inorganic filler 61 that fills a space between the nanoparticles 60. Therefore, the third inorganic filler 61 is formed in a space formed between the nanoparticles 60.

When a voltage is applied to the light-emitting element 20 including the hole transport material such as the nanoparticles 60 in the hole transport layer 22, cations are generated due to ionization of the hole transport material and may move to a side of the light-emitting layer 23 together with holes. However, in the hole transport layer 22, the third inorganic filler 61 located in the space between the nanoparticles 60 inhibits the movement of the cations and prevents the cations from reaching the light-emitting layer 23.

Therefore, the hole transport layer 22 reduces deterioration of the quantum dots 40 of the light-emitting layer 23, and improves reliability and light-emitting efficiency of the light-emitting element 20. The display device 4 includes the light-emitting element 20 with improved reliability and light-emitting efficiency, and thus, the lifetime of the display device 4 is prolonged and power saving is achieved.

In the hole transport layer 22 according to the present embodiment, the hole transport layer 22 includes the third inorganic filler 61, and thus, the holes injected from the anode 21 are also prevented from moving between the hole transport materials. In the light-emitting element 20, excessive holes may be generated in the light-emitting layer 23 depending on the design of the Fermi level of each electrode, the band gap of each layer, and the like. In such a case, the hole transport layer 22 according to the present embodiment suppresses the transport of holes from the anode 21 to the light-emitting layer 23, and thus, the concentration of holes in the light-emitting layer 23 is reduced. Therefore, the hole transport layer 22 suppresses excessive holes in the light-emitting layer 23, and further improves the reliability and the luminous efficiency of the light-emitting element 20.

In the light-emitting layer 23 according to the present embodiment, the second inorganic filler 44 fills a space between the quantum dots 40, but the disclosure is not limited thereto. In the light-emitting layer 23, a ligand such as an organic ligand coordinated to the quantum dot 40 in place of the second inorganic filler 44 may be formed in a space between the quantum dots 40. Also in such a case, the hole transport layer 22 inhibits the movement of cations from the anode 21 to the light-emitting layer 23, and thus, the reliability and the luminous efficiency of the light-emitting element 20 are improved.

The light-emitting element 20 according to the present embodiment may be manufactured by the same manufacturing method as the method for manufacturing the light-emitting element 20 in the second embodiment except for the process for forming the hole transport layer 22 and the electron transport layer 24. In the method for manufacturing the light-emitting element 20 according to the present embodiment, in step S2, a mixed solution obtained by mixing the nanoparticles 60 and the inorganic precursor of the third inorganic filler 61 may be applied onto the anode 21. Next, the mixed solution may be heated to denature the precursor into the third inorganic filler 61, and as a result, the hole transport layer 22 according to the present embodiment may be manufactured. The heating of the mixed solution in step S2 may be performed under the same conditions as for the heating of the mixed solution in step S4 described above. In the method for manufacturing the light-emitting element 20 according to the present embodiment, instead of step S4 and step S5, a layer having an electron transport property may be applied on the light-emitting layer 23 to form a film thereon.

### Band Diagram of Each Component of Light-Emitting Element

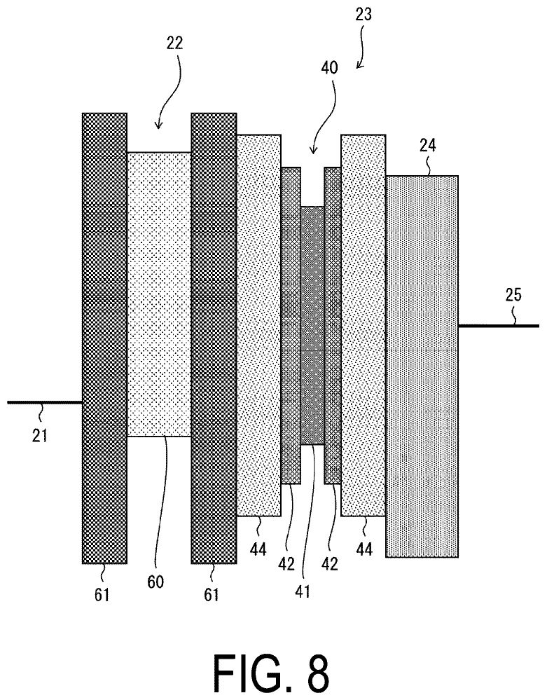

A band gap of components of the light-emitting element 20 according to the present embodiment will be described with reference to FIG. 8. FIG. 8 is a schematic band diagram illustrating an example of a band gap of each component of the light-emitting element 20 according to the present embodiment. In the band diagram illustrated in FIG. 8, band gaps of the nanoparticles 60 and the third inorganic filler 61 of the hole transport layer 22 are illustrated.

As illustrated in FIG. 8, the band gap of the third inorganic filler 61 is equal to or more than the band gap of the second inorganic filler 44. The ionization potential of the third inorganic filler 61 is equal to or more than the ionization potential of the second inorganic filler 44. Note that in the band diagram according to the disclosure, the ionization potential of each component corresponds to the distance from the vacuum level to the lower end of the band gap. Therefore, in the band diagram of FIG. 8, as the lower end of the band gap of a layer is located at the lower side, the ionization potential of the layer is larger. In other words, as the band gap of a layer increases, the ionization potential of the layer tends to increase.

Here, for example, an injection barrier of the hole from a first layer to a second layer corresponds to ionization potential obtained by subtracting the ionization potential of the first layer from the ionization potential of the second layer. Thus, in the present embodiment, the band gap of the third inorganic filler 61 is equal to or larger than the band gap of the second inorganic filler 44, and thus, the barrier of hole injection from the third inorganic filler 61 to the second inorganic filler 44 is further reduced. Therefore, the light-emitting element 20 according to the present embodiment further improves the efficiency of hole injection from the anode 21 to the light-emitting layer 23, and further suppresses excess of electrons in the light-emitting layer 23.

### Fifth Embodiment

### Second Hole Transport Layer

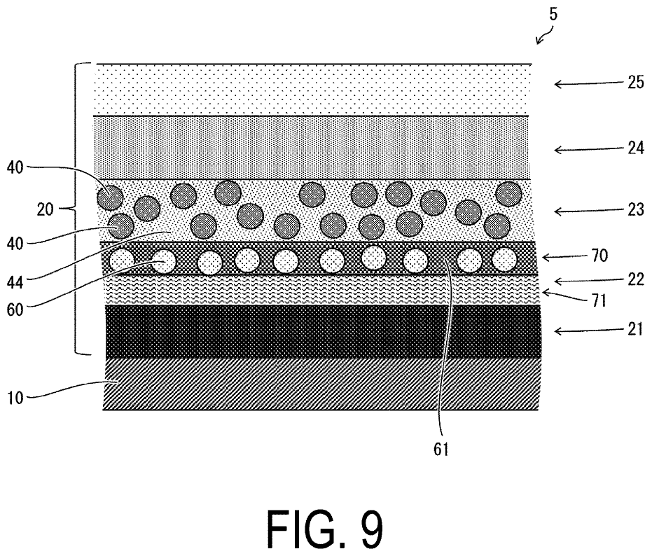

A display device 5 according to the present embodiment will be described with reference to FIG. 9. FIG. 9 is a schematic cross-sectional side view of the display device 5 according to the present embodiment. The display device 5 according to the present embodiment has the same configuration as the display device 4 according to the previous embodiment except for the hole transport layer 22. The hole transport layer 22 according to the present embodiment includes a first hole transport layer 70 in contact with the light-emitting layer 23 and a second hole transport layer 71 in contact with the first hole transport layer 70 in this order from a side of the light-emitting layer 23. In other words, the light-emitting element 20 according to the present embodiment includes the first hole transport layer 70 and the second hole transport layer 71 on the side opposite to the light-emitting layer 23 with respect to the first hole transport layer 70.

The first hole transport layer 70 has the same configuration as the hole transport layer 22 according to the above-described embodiments except for the thickness. The first hole transport layer 70 may have a thickness of, for example, 1 nm or more and 300 nm or less in the layering direction of the light-emitting elements 20 from the position in contact with the light-emitting layer 23.

The second hole transport layer 71 has the same configuration as the first hole transport layer 70 except that the second hole transport layer 71 does not include the third inorganic filler 61. The second hole transport layer 71 includes a hole transport material, such as the nanoparticles 60. The second hole transport layer 71 may have the thickness of, for example, 10 nm or more and 300 nm or less in the layering direction of the light-emitting elements 20 from the position in contact with the first hole transport layer 70.

The light-emitting element 20 according to the present embodiment includes the first hole transport layer 70 being in contact with the light-emitting layer 23 and having the third inorganic filler 61 with which a space between the nanoparticles 60 is filled. Therefore, in the light-emitting element 20, the third inorganic filler 61 can reduce the passage of ions between the nanoparticles 60 in the first hole transport layer 70.

The light-emitting element 20 according to the present embodiment includes the second hole transport layer 71 not including the third inorganic filler 61 in a part of the hole transport layer 22 in the film thickness direction. Therefore, the light-emitting element 20 achieves the above-described suppression of the passage of ions through the hole transport layer 22 while reducing the total amount of the third inorganic filler 61 included in the hole transport layer 22. Therefore, the light-emitting element 20 achieves both cost reduction and improvement in reliability and luminous efficiency of the light-emitting element 20.

Furthermore, in the light-emitting element 20 according to the present embodiment, the thickness of the first hole transport layer 70 including the third inorganic filler 61 that may inhibit the transport of holes from the anode 21 to the light-emitting layer 23 can be reduced. Therefore, the light-emitting element 20 according to the present embodiment can improve the efficiency of hole injection to the light-emitting layer 23, and further suppress excess of electrons in the light-emitting layer 23.

The light-emitting element 20 according to the present embodiment may be manufactured by the same manufacturing method as the method for manufacturing the light-emitting element 20 in the previous embodiment except for the process for forming the hole transport layer 22. In the method for manufacturing the light-emitting element 20 according to the present embodiment, the mixed solution including no inorganic precursor may be applied onto the anode 21, and then the solvent may be dried. Thus, the second hole transport layer 71 may be formed on the anode 21. Next, after the concentrations of the nanoparticles 60 and the inorganic precursor with respect to the solvent of the mixed solution are reduced, the mixed solution may be applied onto the second hole transport layer 71. Accordingly, the first hole transport layer 70 having a reduced film thickness can be formed on the second hole transport layer 71 without changing the application amount of the mixed solution described above, and the hole transport layer 22 according to the present embodiment can be formed.

### Sixth Embodiment

Mineralization of both Hole Transport Layer and Electron Transport Layer

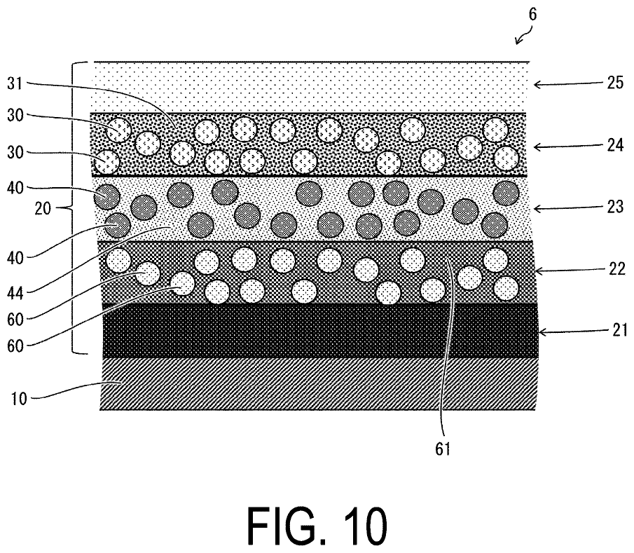

A display device 6 according to the present embodiment will be described with reference to FIG. 10. FIG. 10 is a schematic cross-sectional side view of the display device 6 according to the present embodiment. The display device 6 according to the present embodiment has the same configuration as that of the above-described display device 2 except for the hole transport layer 22. The light-emitting element 20 according to the present embodiment includes the hole transport layer 22 of the above-described display device 4 as the hole transport layer 22.

In other words, the light-emitting element 20 according to the present embodiment includes the electron transport layer 24 serving as the first charge transport layer between the cathode 25 and the light-emitting layer 23. The light-emitting element 20 according to the present embodiment includes the hole transport layer 22 serving as the second charge transport layer which is in contact with the light-emitting layer 23, between the anode 21 and the light-emitting layer 23 and includes the nanoparticles 60 serving as the plurality of second charge transport materials and the third inorganic filler 61 with which a space between the nanoparticles 60 is filled.

The light-emitting element 20 according to the present embodiment includes both the electron transport layer 24 including the first inorganic filler 31 and the hole transport layer 22 including the third inorganic filler 61. Therefore, the light-emitting element 20 suppresses both the arrival of anions from the electron transport layer 24 to the light-emitting layer 23 and the arrival of cations from the hole transport layer 22 to the light-emitting layer 23. Therefore, the light-emitting element 20 reduces deterioration of the quantum dots 40 of the light-emitting layer 23, and further improves the reliability and the light-emitting efficiency of the light-emitting element 20.

In the present embodiment, the first inorganic filler 31 and the third inorganic filler 61 may include the same inorganic material. Thus, the hole transport layer 22 and the electron transport layer 24 can be manufactured by the same process, and the manufacturing process of the light-emitting element 20 is simplified. In particular, in the present embodiment, all of the first inorganic filler 31, the second inorganic filler 44, and the third inorganic filler 61 may include the same inorganic material. This makes it possible to suppress an occurrence of defects such as dangling bonds at both the interface between the hole transport layer 22 and the light-emitting layer 23 and the interface between the light-emitting layer 23 and the electron transport layer 24.

The light-emitting element 20 according to the present embodiment may be manufactured by the same manufacturing method as the method for manufacturing the light-emitting element 20 in the second embodiment except for the process for forming the hole transport layer 22. In the method for manufacturing the light-emitting element 20 according to the present embodiment, the process for forming the hole transport layer 22 may employ the process for forming the hole transport layer 22 in the fourth embodiment.

### Seventh Embodiment

Light-Emitting Element Including both Second Hole Transport Layer and Second Electron Transport Layer

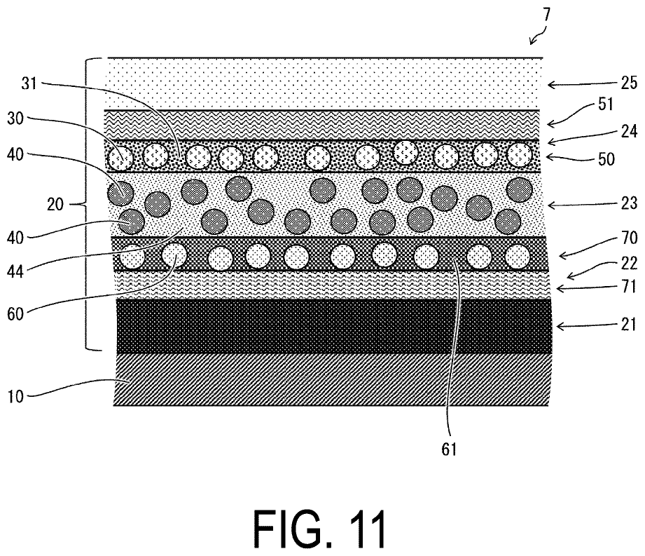

A display device 7 according to the present embodiment will be described with reference to FIG. 11. FIG. 11 is a schematic cross-sectional side view of the display device 7 according to the present embodiment. The display device 7 according to the present embodiment has the same configuration as the above-described display device 3 except for the hole transport layer 22. The light-emitting element 20 according to the present embodiment includes the hole transport layer 22 of the above-described display device 5 serving as the hole transport layer 22.

In other words, the light-emitting element 20 according to the present embodiment includes the first electron transport layer 50 and the second electron transport layer 51 serving as the electron transport layer 24 between the cathode 25 and the light-emitting layer 23 in order from a side of the light-emitting layer 23. The light-emitting element 20 according to the present embodiment includes, as the hole transport layer 22 between the anode 21 and the light-emitting layer 23, the first hole transport layer 70 and the second hole transport layer 71 in order from the side of the light-emitting layer 23.

The light-emitting element 20 according to the present embodiment can reduce the total amount of the first inorganic filler 31 included in the electron transport layer 24 by the second electron transport layer 51 while suppressing the arrival of anions from the electron transport layer 24 to the light-emitting layer 23 by the first electron transport layer 50. In the light-emitting element 20, the second electron transport layer 51 reduces the electrical resistance of the light-emitting element 20 as a whole to save power to the light-emitting element 20. Note that an example of the anion may include a hydroxide ion.

Further, the light-emitting element 20 can reduce the total amount of the third inorganic filler 61 included in the hole transport layer 22 by the second hole transport layer 71 while suppressing the arrival of cations from the hole transport layer 22 to the light-emitting layer 23 by the first hole transport layer 70. In addition, in the light-emitting element 20, the second electron transport layer 51 improves the injection efficiency of holes from the anode 21 to the light-emitting layer 23 and suppresses excess of electrons in the light-emitting layer 23. Note that an example of the cation may include a hydrogen ion.

Therefore, the light-emitting element 20 achieves reduction in deterioration of the quantum dots 40 of the light-emitting layer 23, reduction in cost, power saving of the light-emitting element 20, improvement in reliability, and improvement in luminous efficiency.

The light-emitting element 20 according to the present embodiment may be manufactured by the same manufacturing method as the method for manufacturing the light-emitting element 20 in the third embodiment except for the process for forming the hole transport layer 22. In the method for manufacturing the light-emitting element 20 according to the present embodiment, the process for forming the hole transport layer 22 may employ the process for forming the hole transport layer 22 in the fifth embodiment.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1, 2, 3, 4, 5, 6, 7 Display device
10 Substrate
20 Light-emitting element
21 Anode
22 Hole transport layer
23 Light-emitting layer
24 Electron transport layer
25 Cathode
30, 60 Nanoparticle
31 First inorganic filler
32 First ligand
40 Quantum dot
43 Second ligand
44 Second inorganic filler
50 First electron transport layer
51 Second electron transport layer
61 Third inorganic filler
70 First hole transport layer
71 Second hole transport layer

1. A light-emitting element comprising:
a first electrode;
a second electrode;
a light-emitting layer being located between the first electrode and the second electrode, the light-emitting layer including a plurality of quantum dots; and
a first charge transport layer being located between the first electrode and the light-emitting layer or between the second electrode and the light-emitting layer, the first charge transport layer being in contact with the light-emitting layer,
wherein the first charge transport layer includes a plurality of first charge transport materials and a first inorganic filler with which a space between the plurality of first charge transport materials is filled.

2. The light-emitting element according to claim 1,
wherein the first charge transport layer includes a nanoparticle serving as the plurality of first charge transport materials and a first ligand being coordinatable to the nanoparticle, and
the nanoparticle and the first ligand include an identical chalcogen.

3. The light-emitting element according to claim 1,
wherein the plurality of first charge transport materials include a plurality of materials having compositions different from each other.

4. The light-emitting element according to claim 1,
wherein the light-emitting layer includes a second ligand being coordinatable to the plurality of quantum dots.

5. The light-emitting element according to claim 4, wherein the second ligand includes an organic ligand.

6. The light-emitting element according to claim 4,
wherein the plurality of first charge transport materials and the second ligand include an identical chalcogen.

7. The light-emitting element according to claim 1, further comprising:
a second inorganic filler with which a space between the plurality of quantum dots is filled.

8. The light-emitting element according to claim 7,
wherein the first inorganic filler and the second inorganic filler include an identical inorganic material.

9. The light-emitting element according to claim 7,
wherein a band gap of the first inorganic filler is equal to or less than a band gap of the second inorganic filler.

10. The light-emitting element according to claim 7,
wherein a band gap of the first inorganic filler is equal to or more than a band gap of the second inorganic filler.

11. The light-emitting element according to claim 1,
wherein the first charge transport layer is a first electron transport layer, and the plurality of first charge transport materials are an electron transport material.

12. The light-emitting element according to claim 11, further comprising:
a second electron transport layer including the electron transport material on a side opposite to the light-emitting layer with respect to the first electron transport layer.

13. The light-emitting element according to claim 1,
wherein the first charge transport layer is a first hole transport layer, and the plurality of first charge transport materials are a hole transport material.

14. The light-emitting element according to claim 13, further comprising:
a second hole transport layer including the hole transport material on a side opposite to the light-emitting layer with respect to the first hole transport layer.

15. The light-emitting element according to claim 1, comprising:
the first charge transport layer between the first electrode and the light-emitting layer; and
a second charge transport layer between the second electrode and the light-emitting layer, the second charge transport layer being in contact with the light-emitting layer and including a plurality of second charge transport materials and a third inorganic filler with which a space between the plurality of second charge transport materials is filled.

16. The light-emitting element according to claim 15,
wherein the first inorganic filler and the third inorganic filler include an identical inorganic material.

17. A display device comprising:
the light-emitting element according to claim 1.

18. (canceled)
